(19) United States
(12) Patent Application Publication
(10) Pub. No.: US 2014/0316727 A1
(43) Pub. Date: Oct. 23, 2014

(54) SYSTEM AND METHOD FOR ADJUSTING ENERGY MEASUREMENT INTERVAL TO MEASURE ENERGY CONSUMED IN COMMUNICATION NODE

(71) Applicant: Electronics and Telecommunications Research Institute, Daejeon (KR)

(72) Inventors: Young Min KIM, Daejeon (KR); Boo Geum JUNG, Daejeon (KR); Hea Sook PARK, Daejeon (KR); Ki Cheol JEON, Daejeon (KR); Byungjun AHN, Daejeon (KR)

(73) Assignee: Electronics and Telecommunications Research Institute, Daejeon (KR)

(21) Appl. No.: 14/089,166

(22) Filed: Nov. 25, 2013

(30) Foreign Application Priority Data
Apr. 19, 2013 (KR) 10-2013-0043349

(51) Int. Cl. G01R 21/133

(52) U.S. Cl. CPC G01R 21/133
USPC 702/62

(57) ABSTRACT

A system for adjusting an energy measurement interval in a communication node on a network includes a measurement module configured to calculate a traffic load applied to the communication node in conformity with a traffic load measurement interval and calculate an energy consumption consumed in the communication node in conformity with an energy measurement interval. The system further comprising an information management module and a measurement interval setting module.

### RELATED APPLICATIONS

This application claims the benefit of Korean Patent Application No. 10-2013-0043349, filed on Apr. 19, 2013, which is hereby incorporated by reference as if fully set forth herein.

### FIELD OF THE INVENTION

The present invention relates to a system and method for measuring an energy consumption in a communication node, and more particularly, to a system and method for adjusting an energy measurement interval, which measures an energy consumption in a router, produces an energy profile depending on a traffic load, and calculates an energy consumption rate being consumed in real-time on a basis of the energy profile, thereby controlling the energy measurement interval.

### BACKGROUND OF THE INVENTION

A recent study reports that an energy consumption by the Internet amounts to 5.5% of the global energy consumption, approximately 9 trillion kWh, and the energy consumption will increase to 20 to 25 percent annually.

The crucial point is that, despite of the energy consumption of a huge amount of being made on the Internet, the Internet at current is designed and operated without considering the energy that is consumed. For example, the communication nodes on a network, for example, routers consume the same energy at a peak time or an off-peak time, regardless of the amount of incoming traffic. Therefore, by making the routers enter a standby mode at a time when traffic does not occur, the enormous energy savings can be achieved.

Thus, in recent, while studies on the system to measure the energy consumption in the router are conducted gradually, the technology relevant thereto is not widely known. The International Organization for Standardization (ITU SG5, ATIS) has just introduced an off-line based energy measurement technology and an on-line based energy measurement technology.

Of the technologies, the on-line based energy measurement technology is an essential technique necessary for performing an energy-based control, but now the international standard just deals with only a method for measuring the energy at regular intervals simply. For this method, even though there is no change in energy, the energy measurement is performed continuously, which incurs a separate energy wasting for the energy measurement. Thus, studies are strongly needed on a method to adjust the measurement interval of the energy that can minimize an energy waste for the energy measurement when measuring the energy consumption in the router.

### SUMMARY OF THE INVENTION

In view of the above, the present invention provides a system and method for adjusting a measurement interval of energy consumption in a router in consideration of a traffic load, a network congestion level, and an energy profile in the router.

In accordance with an aspect of an exemplary embodiment of the present invention, there is provided a system for adjusting an energy measurement interval in a communication node on a network, which includes: a measurement module configured to calculate a traffic load applied to the communication node in conformity with a traffic load measurement interval and calculate an energy consumption consumed in the communication node in conformity with an energy measurement interval; an information management module configured to manage information on a maximum traffic load and a maximum energy consumption of the communication node; and a measurement interval setting module configured to set the energy measurement interval using the measured traffic load, the measured energy consumption, the maximum energy consumption and the maximum traffic load.

In the exemplary embodiment, wherein the energy measurement module comprises: a traffic measurement unit configured to measure the traffic load in conformity with the traffic load measurement interval, wherein the measured traffic load is transferred to the measurement interval setting module; and an energy measurement unit configured to measure the energy consumption in conformity with the energy measurement interval, wherein the measured energy consumption is transferred to the measurement interval setting module.

In the exemplary embodiment, wherein the measurement interval setting module comprises: an energy profile modeling unit configured to model the measured traffic load, the measured energy consumption, the maximum energy consumption and the maximum traffic load to derive a model of an energy profile function; and a measurement adjustment unit configured to set the energy measurement interval depending on an energy consumption rate derived from the energy profile function.

In the exemplary embodiment, wherein the energy profile function represents a relationship of a normalized traffic load and a normalized energy consumption; and wherein the normalized traffic load and the normalized energy consumption are calculated from following Equations,

$${ρ}_{nor} = \frac{{ρ}_{t}}{{ρ}_{max}}$$

$$and$$

$${e}_{nor} = \frac{{e}_{t}}{{e}_{max}}$$

where ρₜ denotes the measured traffic load, ρₘₐₓ denotes the maximum traffic load, eₜ denotes the measured energy consumption, and eₘₐₓ denotes the maximum energy consumption.

In the exemplary embodiment, wherein the energy measurement interval is set as a following Equation,

$${T}_{e} = \frac{T}{k}$$

where Tₑ denotes an energy measurement interval which is set, T denotes an initial value of the energy measurement interval, and k is the energy consumption rate.

In the exemplary embodiment, wherein the energy consumption rate is calculated using a following Equation,

$$k = {f}^{′} ( ρ ) = \frac{{f}_{l} ( ρ + Δ ) - {f}_{l} ( {ρ}_{nor} )}{( ρ + Δ ) - {ρ}_{nor}} = \frac{{f}_{l} ( ρ + Δ ) - {f}_{l} ( {ρ}_{nor} )}{Δ}$$

$$where$$

$${f}^{′} ( ρ )$$

denotes a first derivative of the energy profile function, ƒₗ(ρ) denotes an energy profile function, ƒₗ(ρₙₒᵣ) denotes a normalized energy consumption when the normalized traffic load is ρₙₒᵣ, and Δ means a unit traffic load.

In the exemplary embodiment, further comprising: a network congestion notification unit configured to generate a network congestion notification when the measured traffic load exceeds a threshold value to notify a network congestion state of the measurement interval setting module, wherein the measurement interval setting module is configured to set the energy measurement interval to a minimum measurement interval when the measured traffic load exceeds a predetermined threshold value.

In accordance with another aspect of an exemplary embodiment of the present invention, there is provided a method for adjusting an energy measurement interval in a communication node on a network, which includes: calculating a traffic load applied to the communication node in conformity with a traffic load measurement interval; generating a model of an energy profile function using a maximum energy consumption, a maximum energy consumption and the measured traffic load in the communication node; comparing the measured traffic load at current and a previously measured traffic load to determine whether they are the same; when the measured traffic load at current is not equal to the previously measured traffic load, calculating an energy consumption rate indicating an energy needed for the traffic load from the energy profile function; and updating the energy measurement interval depending on the calculated energy consumption rate.

In the exemplary embodiment, further comprising: when the measured traffic load at current is equal to the previously measured traffic load, setting the energy measurement interval to a previous energy measurement interval.

In the exemplary embodiment, wherein the energy measurement interval is set to a minimum measurement interval when the measured traffic load exceeds a predetermined threshold value.

In the exemplary embodiment, wherein the energy profile function represents a relationship of a normalized traffic load and a normalized energy consumption; wherein the normalized traffic load and the normalized energy consumption are calculated from following Equations,

$${ρ}_{nor} = \frac{{ρ}_{t}}{{ρ}_{max}}$$

$$and$$

$${e}_{nor} = \frac{{e}_{t}}{{e}_{max}}$$

where ρₜ denotes the measured traffic load, ρₘₐₓ denotes the maximum traffic load, eₜ denotes the measured energy consumption, and eₘₐₓ denotes the maximum energy consumption.

In the exemplary embodiment, wherein the energy measurement interval is updated as in a following Equation,

$${T}_{e} = \frac{T}{k}$$

where Tₑ denotes an energy measurement interval which is updated, T denotes an initial value of the energy measurement interval, and k is the energy consumption rate.

wherein the energy consumption rate is calculated from a following Equation,

$$k = {f}^{′} ( ρ ) = \frac{{f}_{l} ( ρ + Δ ) - {f}_{l} ( {ρ}_{nor} )}{( ρ + Δ ) - {ρ}_{nor}} = \frac{{f}_{l} ( ρ + Δ ) - {f}_{l} ( {ρ}_{nor} )}{Δ}$$

where ƒ′(ρ) denotes a first derivative of the energy profile function, ƒₗ(ρ) denotes an energy profile function, ƒₗ(ρₙₒᵣ) denotes a normalized energy consumption when the normalized traffic load is ρₙₒᵣ, and Δ means a unit traffic load.

As described above, in accordance with the system and method for adjusting the energy measurement interval, it is possible not only to reduce memory resources, measurement time and efforts, but also to save the energy consumed to measure the energy consumption. Further, it is also possible to derive an energy profile function through an efficient energy measurement in accordance with the embodiment of the present invention.

### BRIEF DESCRIPTION OF THE DRAWINGS

The above and other objects and features of the present invention will become apparent from the following description of the embodiments given in conjunction with the accompanying drawings, in which:

FIG. 1 is a block diagram of a system for adjusting an energy measurement interval based on an energy profile in accordance with an embodiment of the present invention;

FIG. 2 is a flow diagram illustrating a procedure for deriving an energy profile function in accordance with an embodiment of the present invention;

FIG. 3 is a flow diagram illustrating a procedure for setting an energy measurement interval based on an energy profile in accordance with an embodiment of the present invention; and

FIG. 4 is a graph of an energy profile function illustrating a procedure for calculating an energy consumption rate based on an energy profile function in accordance with an embodiment of the present invention.

### DETAILED DESCRIPTION OF THE EMBODIMENTS

Hereinafter, the embodiments of the present invention will be described in detail with reference to the accompanying drawings. In the following description, well-known functions or constitutions will not be described in detail if they would unnecessarily obscure the embodiments of the invention. Further, the terminologies to be described below are defined in consideration of functions in the invention and may vary depending on a user's or operator's intention or practice. Accordingly, the definition may be made on a basis of the content throughout the specification.

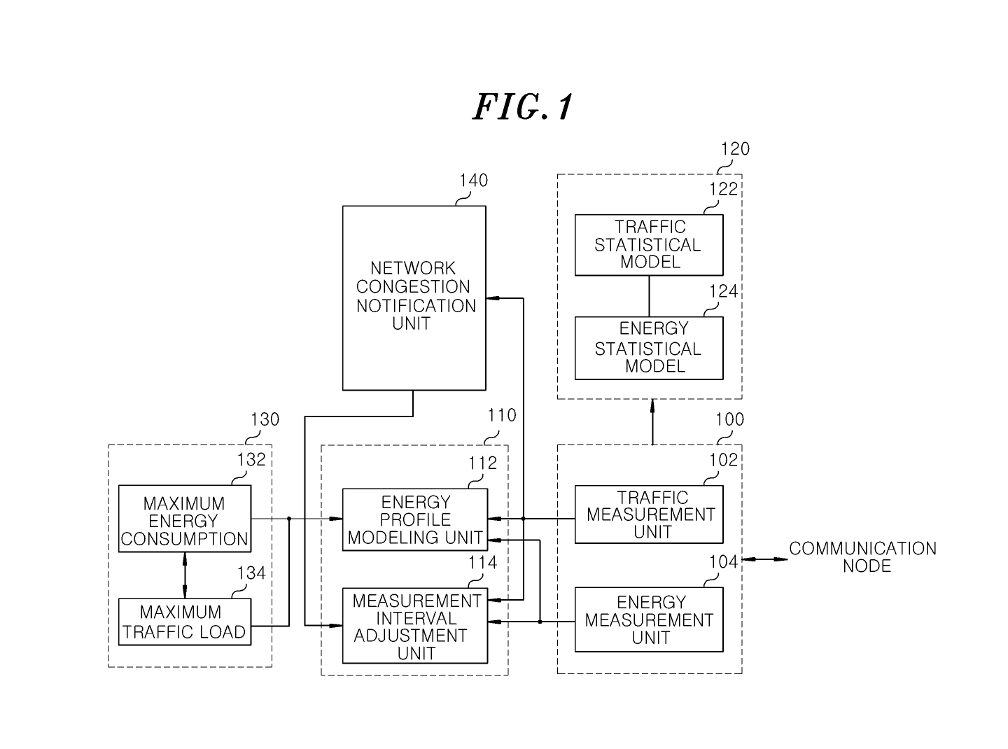

FIG. 1 is a block diagram of a system for adjusting an energy measurement interval based on an energy profile in accordance with an embodiment of the present invention.

A system of the embodiment of the present invention includes a measurement module 100, a measurement interval setting module 110, a database 120, an information management module 130 and a network congestion notification unit 140.

The measurement module 100 measures traffic load applied to in a communication node, for example, a router, and energy consumption in the router in a measurement interval. The measurement module 100 includes a traffic measurement unit 102 and an energy measurement unit 104. The traffic measurement unit 102 measures the traffic load on the communication node in conformity with a traffic load measurement interval and forwards the measured traffic load to the measurement interval setting module 110. Further, the traffic load, which is measured in the traffic measurement unit 102, is also stored in the databases 120. The energy measurement unit 104 measures the energy consumption in the communication node in conformity with the energy measurement interval, and the measured energy consumption is forwarded to the measurement interval setting module 110. Further, the energy consumption measured by the energy measurement unit 104 is also stored in the databases 120.

When the traffic load is a value equal to or more than a threshold value, the network congestion notification unit 140 generates a network congestion notification indicating that the network is congested to notify a network congestion state of the measurement interval setting module 110. Thus, the measurement interval setting module 110 internally sets a network congestion mode to an ‘ON’ state.

The information management module 130 plays a role of managing and storing basic information on the communication node or information provided via a field of a MIB (Management Information Base) of an SNMP (Simple Network Management Protocol). The information that is managed and stored by the information management module 130 includes a maximum energy consumption 132 and a maximum traffic load 134 and these pieces of information are transferred to the measurement interval setting module 110.

The measurement interval setting module 110 receives the traffic load measured by the traffic measurement unit 102 and the energy consumption measured by the energy measurement unit 104. The measurement interval setting module 110 also receives the maximum energy consumption 132 and the maximum traffic load 134 provided from the information management module 130. Further, the measurement interval setting module 110 models the traffic load, the energy consumption, the maximum energy consumption 132 and the maximum traffic load 134, to form a model of an energy profile function. Such a measurement interval setting module 110 includes an energy profile modeling unit 112 and a measurement interval adjustment unit 114.

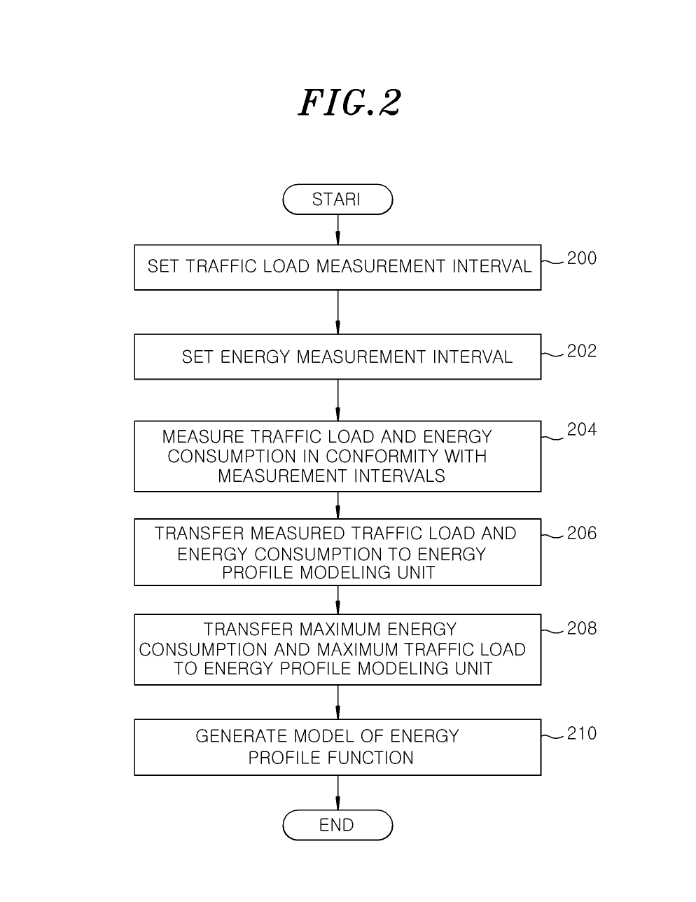

The energy profile function is defined as the energy consumption to the traffic load and is stored the energy profile modeling unit 112. The procedure of deriving a model of the energy profile function will be described with reference to FIG. 2 as below. In addition, the energy profile modeling unit 112 calculates an energy consumption rate from the model of the energy profile function.

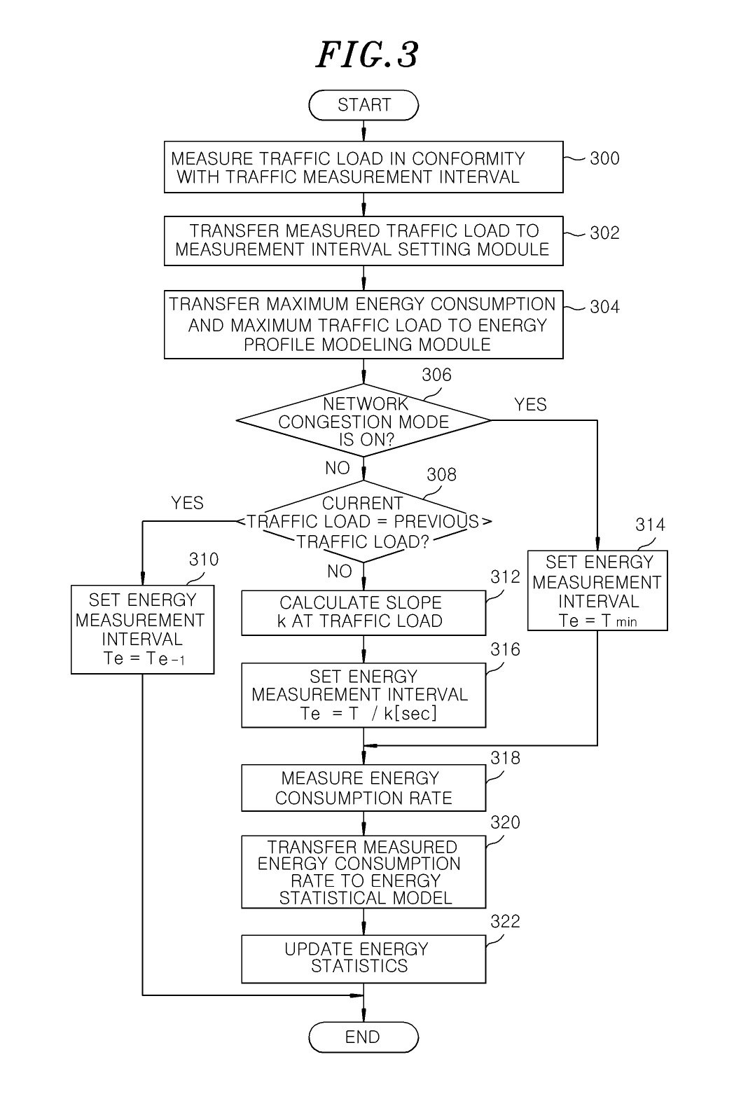

The measurement interval adjustment unit 114 updates the energy measurement interval by using the energy consumption ratio calculated by the energy profile modeling unit 112, the traffic load provided from the traffic measurement unit 102, the network congestion status provided from the network congestion notification unit 140, and the maximum energy consumption 132 and the maximum traffic load 134 from the information management module 130. The updated energy measurement interval is provided to the measurement interval setting module 110. A procedure of setting the energy measurement interval will be described with reference to FIG. 3.

The database 120 includes a traffic statistical model 122 that stores statistical information on the traffic load (for example, the mean and standard deviation of the traffic road) and an energy statistical model 124 that stores statistic information on the energy consumption (for example, the mean and standard deviation value of the energy consumption).

The traffic statistical model 122 updates the statistical information on a basis of a current traffic load measured at present by the traffic measurement unit 102 in the measurement module 100 and a previous traffic load statistics that have been stored in advance. The energy statistical model 124 updates the statistical information on a basis of a current energy consumption measured at present by the energy measurement unit 104 in the measurement module 100 and a previous energy consumption statistics that have been stored in advance.

FIG. 2 is a flow diagram illustrating a procedure for deriving the energy profile function in accordance with an embodiment of the present invention.

The energy profile function may be derived from the two methods, i.e., a dynamic method and a static method. First, the static method is a method to derive the energy profile function by applying a value provided via the MIB of SNMP, or by directly applying a value contained internally in the system itself. Meanwhile, the Dynamic method is to derive the energy profile function through the measurement, as shown in FIG. 2. Derivation of the energy profile function in accordance with the embodiment may be performed by the measurement module 100 and the measurement interval setting module 110.

First, in operation 200, the traffic load measuring unit 102 in the measurement module 100 sets a traffic load measurement interval Tₚ to an initial value T of the traffic load measurement interval. In other words, Tₚ=T where T has a unit of second (sec).

Similarly, in operation 202, the energy measurement unit 104 in the measurement module 100 set an energy measurement interval Tₑ to an initial value of the energy measurement interval. In other words, Tₑ=T where T has a unit if second (sec).

Thereafter, in operation 204, a traffic load ρₜ and an energy consumption are measured respectively by the traffic measurement unit 102 and the energy measurement unit 104 in the measurement module 100.

In operation 206, the traffic load ρₜ and the energy consumption eₜ measured by the traffic measurement unit 102 and the energy measurement unit 104 are transferred to the energy profile modeling unit 112 in the measurement interval setting module 110.

In operation 208, a maximum energy consumption eₘₐₓ and a maximum traffic load ρₘₐₓ, which are provided from the information management module 130, are transferred to the energy profile modeling unit 112 in the measurement interval setting module 110.

In an operation 210, the energy profile modeling unit 112, as shown in a following Equation 1, calculates a normalized traffic load ρₙₒᵣ by using the ratio of the traffic load occupied in the maximum traffic load ρₘₐₓ. Further, the energy profile modeling unit 112, as shown in a following Equation 2, calculates a normalized energy consumption eₙₒᵣ by using the ratio of the energy consumption occupied in the maximum energy consumption eₘₐₓ. The normalized traffic load ρₙₒᵣ and the normalized energy consumption eₙₒᵣ are applied to derive a model of the energy profile function.

$$\begin{matrix}{ρ}_{nor} = \frac{{ρ}_{t}}{{ρ}_{max}} & Equation 1 \\ {e}_{nor} = \frac{{e}_{t}}{{e}_{max}} & Equation 2\end{matrix}$$

As will be described below, the energy profile function is a function showing the relationship between the normalized traffic load and the normalized energy consumption.

FIG. 3 is a flowchart illustrating a procedure for setting an energy measurement interval based on an energy profile in accordance with an embodiment of the present invention.

It is assumed in the method of FIG. 3 that an energy profile function has already been obtained from the energy measuring unit 104. If the energy profile function is given, there will be no need to measure an energy consumption since the energy consumption can be predicted with only a value of a traffic load.

First, in an operation 300, a traffic load ρₜ is calculated by the measurement module 100 in conformity with the traffic load measurement interval. In an operation 302, the measured traffic load ρₜ is forwarded to the measurement interval adjustment unit 114 in the measurement interval setting module 110 and the traffic load statistics model 122 in the database 120.

In an operation 304, the maximum energy consumption eₘₐₓ and the maximum traffic load ρₘₐₓ are forwarded from the information management module 130 to the measurement interval setting module 110.

In an operation 306, the measurement interval setting module 110 determines whether the network congestion mode is set to an ‘ON’ state to adjust the energy measurement interval. More specifically, when it is determined that the network congestion mode is set to an ‘ON’ state, the method goes to an operation 314 where the energy measurement interval Tₑ is set to a threshold value Tₘᵢₙ having a minimum energy measurement interval. However, when it is determined that the network congestion mode is not set to an ‘ON’ state, the method proceeds to an operation 308.

In the operation 308, the measurement interval setting module 110 determines whether a current traffic load ρₜ measured at present is equal to a previous traffic load ρₜ₋₁, which was measured on a previous measurement interval. This determination is used for the purpose of avoiding the re-measurement of the current energy consumption when the current and previous energy consumptions are the same to save an energy waste consumed to perform the energy measurement. As a result of the determination of the operation 308, it is determined that the current traffic load ρₜ is equal to the previous traffic load ρₜ₋₁, the method advances to an operation 310 where the energy measurement interval Tₑ is set to the same value as the previous measurement interval, and then the method ends. However, when it is determined that the current traffic load ρₜ is not equal to the previous traffic load ρₜ₋₁, the method proceeds to an operation 312.

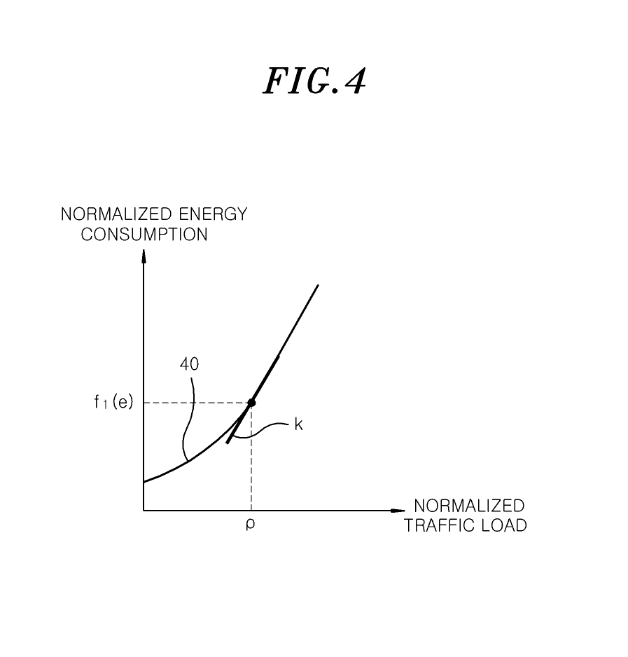

In the operation 312, the energy profile modeling unit 112 calculates a slope of the energy profile function at values of the normalized traffic load value by the Equation 1. Here, the slope of the energy profile function means an energy consumption rate. The calculation of the slope will be described with reference to FIG. 4.

In an operation 316, the energy measurement interval is newly set to be a following Equation 3 using the calculated energy consumption rate, which is the slope k.

$${T}_{e} = \frac{T}{k} \qquad Equation 3$$

where denotes an energy measurement interval which is newly set, and denotes an initial value of the measurement interval.

The initial value of the measurement interval may be set to a predetermined time interval (sec), and alternatively, it may be set to a previous energy measurement interval.

Subsequently, an energy consumption is calculated by the energy measurement unit 104 in the measurement module 100, in an operation 318, and the measured energy consumption is then transferred to the energy statistical model 124 in the database the database 120.

In an operation 322, the energy statistical model 124 in the database 120 updates the energy statistical information based on the energy consumption which is transferred from energy measurement unit the energy measurement unit 104, and the method ends.

FIG. 4 is a graph of an energy profile function illustrating a procedure for calculating an energy consumption rate based on an energy profile in accordance with an embodiment of the present invention.

As known from FIG. 4, an energy profile function 40 is a function having a relationship in which a horizontal axis represents a variable of the normalized traffic load and a vertical axis represents a variable of a normalized energy consumption. In this regard, it is noted that the normalized traffic load and the normalized energy consumption are calculated using the Equations 1 and 2, respectively.

For example, when an energy profile function is defined as ƒ(ρ), a normalized energy consumption is ƒ(ρₙₒᵣ) when a normalized traffic load is ρₙₒᵣ where a slope is defined as k. The slope k can be obtained as a first derivative ƒ′(ρ) of the energy profile function as in a following Equation 4.

$$k = {f}^{′} ( ρ ) = \frac{f ( ρ + Δ ) - f ( {ρ}_{nor} )}{( ρ + Δ ) - {ρ}_{nor}} = \frac{f ( ρ + Δ ) - f ( {ρ}_{nor} )}{Δ} \qquad Equation 4$$

In Equation 4, Δ means a unit traffic load, e.g., a value of 0.01.

While the present invention has been shown and described with reference to specific matters such as the concrete elements and the definitive embodiments and drawings, it should be noted by those skilled in the art that these are provided only for the general understanding of the present invention. Therefore, the present invention may not be limited to the foregoing embodiments and may be changed and modified in various forms from the above description by those skilled in the art.

What is claimed is:

1. A system for adjusting an energy measurement interval in a communication node on a network, the system comprising:
a measurement module configured to calculate a traffic load applied to the communication node in conformity with a traffic load measurement interval and calculate an energy consumption consumed in the communication node in conformity with an energy measurement interval;
an information management module configured to manage information on a maximum traffic load and a maximum energy consumption of the communication node; and
a measurement interval setting module configured to set the energy measurement interval using the measured traffic load, the measured energy consumption, the maximum energy consumption and the maximum traffic load.

2. The system of claim 1, wherein the energy measurement module comprises:
a traffic measurement unit configured to measure the traffic load in conformity with the traffic load measurement interval, wherein the measured traffic load is transferred to the measurement interval setting module; and
an energy measurement unit configured to measure the energy consumption in conformity with the energy measurement interval, wherein the measured energy consumption is transferred to the measurement interval setting module.

3. The system of claim 2, wherein the measurement interval setting module comprises:
an energy profile modeling unit configured to model the measured traffic load, the measured energy consumption, the maximum energy consumption and the maximum traffic load to derive a model of an energy profile function; and
a measurement adjustment unit configured to set the energy measurement interval depending on an energy consumption rate derived from the energy profile function.

4. The system of claim 1, wherein the energy profile function represents a relationship of a normalized traffic load and a normalized energy consumption; and
wherein the normalized traffic load and the normalized energy consumption are calculated from following Equations,
$${ρ}_{nor} = \frac{{ρ}_{t}}{{ρ}_{max}}$$
$$and$$
$${e}_{nor} = \frac{{e}_{t}}{{e}_{max}}$$
where ρₜ denotes the measured traffic load, ρₘₐₓ denotes the maximum traffic load, eₜ denotes the measured energy consumption, and eₘₐₓ denotes the maximum energy consumption.

5. The system of claim 3, wherein the energy measurement interval is set as a following Equation,
$${T}_{e} = \frac{T}{k}$$
where Tₑ denotes an energy measurement interval which is set, T denotes an initial value of the energy measurement interval, and k is the energy consumption rate.

6. The system of claim 5, wherein the energy consumption rate is calculated using a following Equation,
$$k = {f}^{′} ( ρ ) = \frac{f ( ρ + Δ ) - f ( {ρ}_{nor} )}{( ρ + Δ ) - {ρ}_{nor}} = \frac{f ( ρ + Δ ) - f ( {ρ}_{nor} )}{Δ}$$
where ƒ′(ρ) denotes a first derivative of the energy profile function, ƒ(ρ) denotes an energy profile function, ƒ(ρₙₒᵣ) denotes a normalized energy consumption when the normalized traffic load is ρₙₒᵣ and Δ means a unit traffic load.

7. The system of claim 3, further comprising:
a network congestion notification unit configured to generate a network congestion notification when the measured traffic load exceeds a threshold value to notify a network congestion state of the measurement interval setting module,
wherein the measurement interval setting module is configured to set the energy measurement interval to a minimum measurement interval when the measured traffic load exceeds a predetermined threshold value.

8. A method for adjusting an energy measurement interval in a communication node on a network, the method comprising:
calculating a traffic load applied to the communication node in conformity with a traffic load measurement interval;
generating a model of an energy profile function using a maximum energy consumption, a maximum energy consumption and the measured traffic load in the communication node;
comparing the measured traffic load at current and a previously measured traffic load to determine whether they are the same;
when the measured traffic load at current is not equal to the previously measured traffic load, calculating an energy consumption rate indicating an energy needed for the traffic load from the energy profile function; and
updating the energy measurement interval depending on the calculated energy consumption rate.

9. The method of claim 8, further comprising:
when the measured traffic load at current is equal to the previously measured traffic load, setting the energy measurement interval to a previous energy measurement interval.

10. The method of claim 8, wherein the energy measurement interval is set to a minimum measurement interval when the measured traffic load exceeds a predetermined threshold value.

11. The method of claim 8, wherein the energy profile function represents a relationship of a normalized traffic load and a normalized energy consumption;
wherein the normalized traffic load and the normalized energy consumption are calculated from following Equations,
$${ρ}_{nor} = \frac{{ρ}_{t}}{{ρ}_{max}}$$
$$and$$
$${e}_{nor} = \frac{{e}_{t}}{{e}_{max}}$$
where ρₜ denotes the measured traffic load, ρₘₐₓ denotes the maximum traffic load, eₜ denotes the measured energy consumption, and eₘₐₓ denotes the maximum energy consumption.

12. The method of claim 8, wherein the energy measurement interval is updated as in a following Equation,
$${T}_{e} = \frac{T}{k}$$
where Tₑ denotes an energy measurement interval which is updated, T denotes an initial value of the energy measurement interval, and k is the energy consumption rate.

13. The method of claim 12, wherein the energy consumption rate is calculated from a following Equation,
$$k = {f}^{′} ( ρ ) = \frac{f ( ρ + Δ ) - f ( {ρ}_{nor} )}{( ρ + Δ ) - {ρ}_{nor}} = \frac{f ( ρ + Δ ) - f ( {ρ}_{nor} )}{Δ}$$
where ƒ′(ρ) denotes a first derivative of the energy profile function, ƒ(ρ) denotes an energy profile function, ƒ(ρₙₒᵣ) denotes a normalized energy consumption when the normalized traffic load is ρₙₒᵣ, and Δ means a unit traffic load.
